(19) United States
(12) Patent Application Publication
(10) Pub. No.: US 2008/0093738 A1
(43) Pub. Date: Apr. 24, 2008

(54) CHIP STRUCTURE AND WAFER STRUCTURE

(75) Inventor: Jui-Chang Lin, Taichung County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, omitted

(73) Assignee: NOVATEK MICROELECTRONICS CORP., Hsinchu (TW)

(21) Appl. No.: 11/745,461

(22) Filed: May 8, 2007

(30) Foreign Application Priority Data
Oct. 19, 2006 (TW) 95138533

(51) Int. Cl. H01L 23/48

(52) U.S. Cl. 257/737; 257/E23.01

(57) ABSTRACT

A chip structure including a substrate, at least one pad, at least one protruding pattern, a passivation layer, and at least one bump is provided. The substrate has a circuit unit. The pad and the protruding pattern are disposed on the circuit unit, and the pad is surrounded by the protruding pattern. The circuit unit, the pad, and the protruding pattern are covered by the passivation layer. The passivation layer has at least one opening exposing a part of the pad. The bump is disposed on the passivation layer and electrically connected to the pad. The bump overlaps the protruding pattern and the pad, and the top surface of the bump has a protrusion pattern corresponding to the protruding pattern.

### CROSS-REFERENCE TO RELATED APPLICATION

This application claims the priority benefit of Taiwan application serial no. 95138533, filed Oct. 19, 2006. All disclosure of the Taiwan application is incorporated herein by reference.

### BACKGROUND OF THE INVENTION

1. Field of the Invention

The present invention relates to an integrated circuit structure. More particularly, the present invention relates to a chip structure and a wafer structure.

2. Description of Related Art

The rapid advancement of modern information society mostly benefits from the rapid progress in developing semiconductor devices and human-machine display apparatus. With regard to displays, cathode ray tubes (CRT) have monopolized the display market in recent years due to superior display quality and cost-effectiveness. However, in the environment where a plurality of terminals/display apparatus is operated by a single person on the same desk, or in consideration of environmental protection, since CRT has the disadvantages of having a large volume and consuming a great amount of power, the current requirements being light, thin, short, small, and having low power consumption cannot be met. Therefore, liquid crystal displays (LCD) having high picture quality, preferred space utilization, low power consumption, and low radiation have gradually become predominated in the market.

Regarding the manufacturing of LCDs, in order to enhance the packing density, to reduce the weight of LCDs, to use less materials to reduce manufacturing cost, and to enhance the resolution of LCDs, manufacturers generally electrically connect drive chips to LCD panels through a chip on glass (COG) process.

Referring to FIG. 1, a schematic view of a conventional drive chip of an LCD is shown, the drive chip 100 includes a substrate 110, a plurality of aluminum pads 120 (only one is shown), a passivation layer 130, a plurality of under ball metallurgy (UBM) layers 140 (only one is shown), and a plurality of gold bumps 150 (only one is shown). The substrate 110 has a circuit unit 112. The aluminum pad 120 is disposed on the circuit unit 112. The circuit unit 112 and the aluminum pad 120 are covered by the passivation layer 130. The passivation layer 130 has an opening 132 exposing a part of the aluminum pad 120. The UBM layer 140 covers the passivation layer 130 and is electrically connected to the aluminum pad 120 through the opening 132. The gold bump 150 is disposed on and electrically connected to the UBM layer 140.

It should be noted that a height difference occurs between a pad surface 122 and a circuit unit surface 112a, and thus the passivation layer 130 surrounding the aluminum pad 120 has a ring protrusion P. Since the UBM layer 140 and the gold bump 150 are both stacked on the aluminum pad 120 through a lithography/etching process and an electroplating process, a top surface 152 of the gold bump 150 also has a ring protrusion Q corresponding to the ring protrusion P.

As for the aforementioned drive chip 100, manufactures may electrically connect the drive chip 100 to an LCD through a COG process. FIGS. 2A and 2B are schematic views of the process flow of pressing the drive chip in FIG. 1 onto an LCD. Referring to FIG. 2A, an LCD 200 is first provided, wherein a plurality of contacts 210 (only one is shown) is formed on a surface of the LCD 200. Then, an anisotropic conductive film (ACF) 300 is covered on the contact 210, wherein the ACF 300 includes an insulating adhesive 310 and a plurality of conductive particles 320. Next, the gold bump 150 is faced to the contact 210 and the drive chip 100 is pressed to the LCD 200.

Referring to FIG. 2B, when the gold bump 150 contacts the contact 210, a part of the insulating adhesive 310 and a part of the conductive particles 320 are trapped on the top surface 152 by the ring protrusion Q of the gold bump 150. In this manner, through the gold bump 150, the conductive particles 320 trapped in the ring protrusion Q, and the contact 210, the drive chip 100 is electrically connected to the LCD 200. Subsequently, the insulating adhesive 310 and the conductive particles 320 that are not trapped in the ring protrusion Q are removed.

Referring to FIG. 1 again, generally speaking, in order to protect the aluminum pad 120 from being contaminated during the process of forming the gold bump 150, the size of the gold bump 150 is adjusted to form a distance d between a side wall of the gold bump 150 and the opening 132, wherein d≧4 μm.

However, with the continuous development of manufacturing technology, the pitch between two adjacent contacts 210 on the LCD 200 is gradually shortened, and accordingly, the size of the gold bump 150 on the drive chip 100 also becomes small. Therefore, when the size of the gold bump 150 is miniaturized and the distance d between the side wall of the gold bump 150 and the opening 132 is maintained, the ratio R of the area of the protrusion on the top surface 152 to the area of the top surface 152 (i.e., the ratio R=the area of the ring protrusion Q/the area of the top surface 152) will increase as the size of the gold bump 150 becomes small. It should be noted that the larger the ratio R is, the less the number of the conductive particles 320 are trapped in the ring protrusion Q. As a result, the yield of the COG process is easily degraded.

### SUMMARY OF THE INVENTION

Accordingly, the present invention is directed to a chip structure and a wafer structure with a plurality of bumps, wherein the bumps are suitable for trapping conductive particles in an anisotropic conductive film (ACF) on the surfaces of the bumps.

The present invention provides a chip structure, which comprises a substrate, at least one pad, at least one protruding pattern, a passivation layer, and at least one bump. The substrate has a circuit unit. The pad and the protruding pattern are disposed on the circuit unit, wherein the pad is surrounded by the protruding pattern. The circuit unit, the pad and the protruding pattern are covered by the passivation layer. The passivation layer has at least one opening exposing a part of the pad. The bump is disposed on the passivation layer and electrically connected to the pad. The bump overlaps the protruding pattern and the pad, and the top surface of the bump has a protrusion pattern corresponding to the protruding pattern.

According to an embodiment of the present invention, the chip structure further comprises a UBM layer disposed on the passivation layer and between the bump and the pad.

According to an embodiment of the present invention, the protruding pattern is not connected to the pad.

According to an embodiment of the present invention, the material of the protruding pattern is metal. Furthermore, the material of the protruding pattern is the same as that of the pad.

According to an embodiment of the present invention, the protruding pattern is a continuous pattern. Furthermore, the continuous pattern has a ring protruding pattern.

According to an embodiment of the present invention, the protruding pattern is a discontinuous pattern. Furthermore, the protruding pattern comprises a plurality of protuberances separated from each other.

According to an embodiment of the present invention, the material of the bump is gold.

The present invention further provides a wafer structure, which comprises a substrate, a plurality of pads, a plurality of protruding patterns, a passivation layer, and a plurality of bumps. The substrate has a plurality of circuit units. The pads and the protruding patterns are disposed on the circuit layers, and each of the pads is surrounded by the corresponding protruding pattern. The circuit units, the pads, and the protruding patterns are covered by the passivation layer. The passivation layer has a plurality of openings each of which exposes a part of one of the pads. The bumps are disposed on the passivation layer and electrically connected to the corresponding pads, wherein each of the bumps overlaps the corresponding protruding pattern and the corresponding pad, and the top surfaces of the bumps have protrusion patterns corresponding to the protruding patterns.

According to an embodiment of the present invention, the wafer structure further comprises a plurality of UBM layers disposed on the passivation layer and disposed between the bumps and the pads.

According to an embodiment of the present invention, the protruding patterns are not connected to the pads.

According to an embodiment of the present invention, the material of the protruding patterns is metal. Furthermore, the material of the protruding patterns is the same as that of the pads.

According to an embodiment of the present invention, each of the protruding patterns is a continuous pattern. Furthermore, each of the continuous patterns has a ring protruding pattern.

According to an embodiment of the present invention, each of the protruding patterns is a discontinuous pattern. Furthermore, each of the protruding patterns comprises a plurality of protuberances separated from each other.

According to an embodiment of the present invention, the material of the bumps is gold.

In the present invention, the top surfaces of the bumps have a plurality of protrusion patterns corresponding to the protruding patterns. Therefore, compared with the conventional art, in the present invention, when the bumps of the chip structure are pressed onto the corresponding contacts of a circuit device through an ACF, much more conductive particles may be trapped between the top surfaces of the bumps and the contacts, and the bumps are electrically connected to the contacts through the conductive particles.

In order to the make aforementioned and other objects, features and advantages of the present invention comprehensible, a preferred embodiment accompanied with figures are described in detail below.

It is to be understood that both the foregoing general description and the following detailed description are exemplary, and are intended to provide further explanation of the invention as claimed.

### BRIEF DESCRIPTION OF THE DRAWINGS

FIG. 1 is a schematic view of a conventional drive chip of an LCD.

FIGS. 2A and 2B are schematic views of the process flow of pressing the drive chip in FIG. 1 onto an LCD.

FIG. 3 is a schematic view of the wafer structure according to an embodiment of the present invention.

FIGS. 4A-4E are schematic views showing possible shapes of the protruding patterns 1300 in FIG. 3.

FIG. 5 is a schematic view showing the chip structure sawed from the wafer structure in FIG. 3.

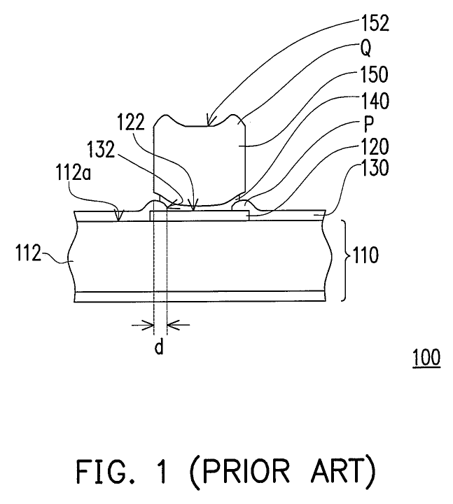

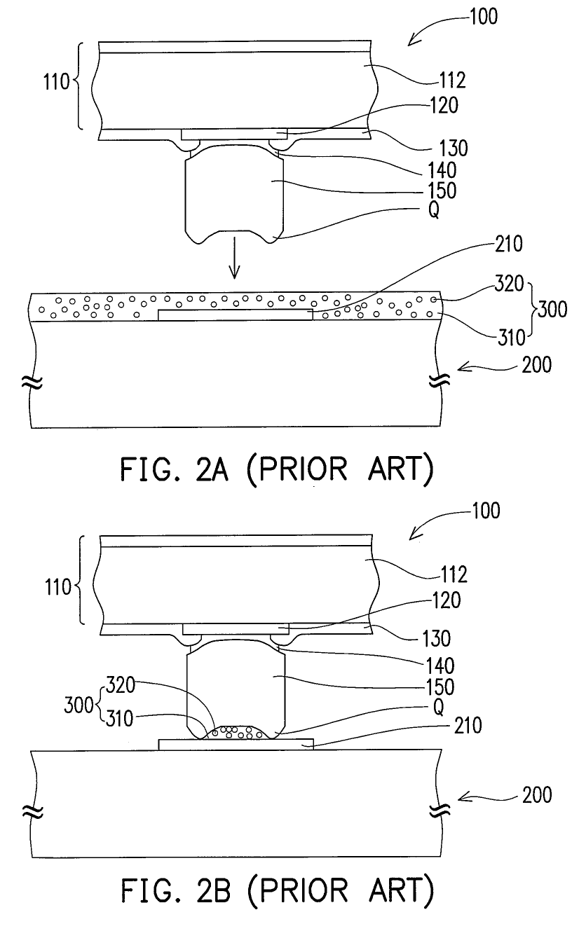

### DESCRIPTION OF EMBODIMENTS

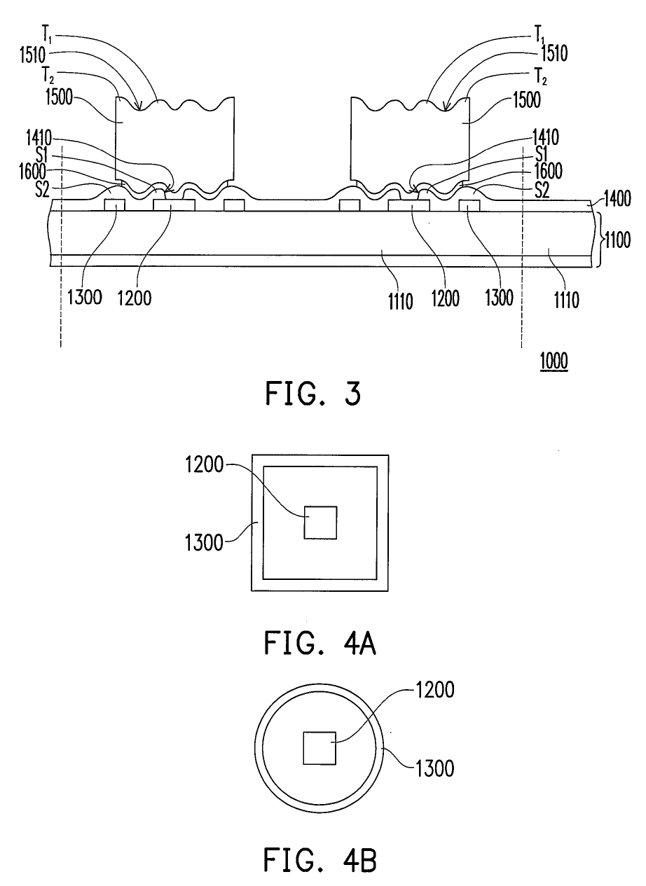

FIG. 3 is a schematic view of the wafer structure according to an embodiment of the present invention. Referring to FIG. 3, a wafer structure 1000 includes a substrate 1100, a plurality of pads 1200, a plurality of protruding patterns 1300, a passivation layer 1400, and a plurality of bumps 1500. The substrate 1100 has a plurality of circuit units 1110. The pads 1200 are disposed on the circuit units 1110 through, for example, a lithography/etching process, wherein the material of the pads 1200 is, for example, aluminum, copper, or other conductive materials. The protruding patterns 1300 are disposed on the circuit units 1110 through, for example, the lithography/etching process, and each of the protruding patterns 1300 surrounds the corresponding pad 1200, wherein the protruding patterns 1300 are not connected to the pads 1200. The material of the protruding patterns 1300 is conductive or non-conductive. The material of the conductive protruding patterns 1300 includes aluminum, copper, or other conductive materials.

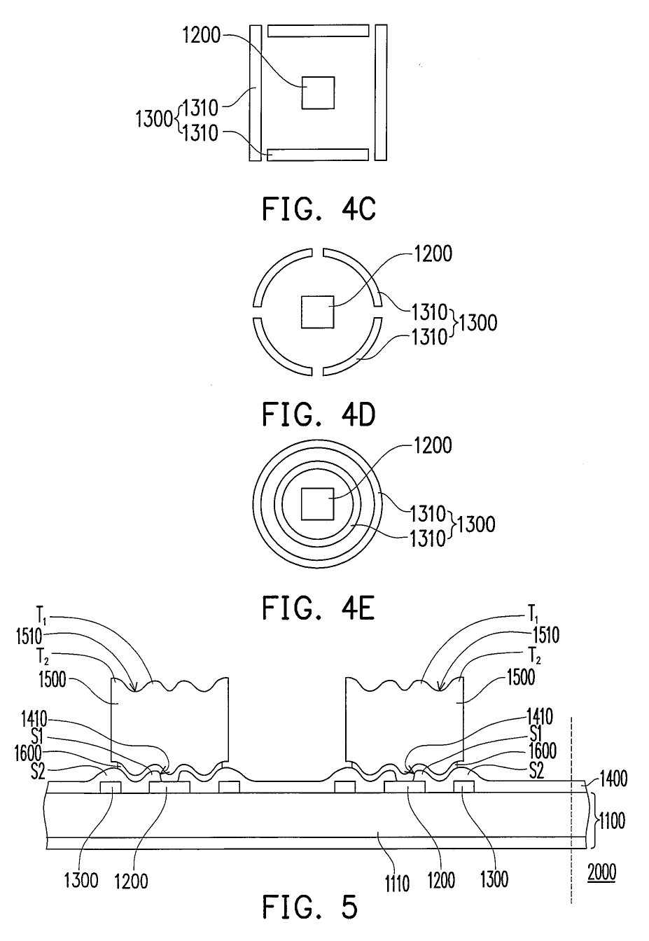

The possible shapes of the protruding patterns 1300 will be introduced below. Referring to FIGS. 4A-4E, the possible shapes of the protruding patterns 1300 in FIG. 3 are shown. It should be noted that, for the purpose of convenient illustration, only the protruding patterns 1300 and the pads 1200 are shown in FIGS. 4A-4E and other components are omitted. The protruding patterns 1300 may be continuous patterns or discontinuous patterns. If the protruding patterns 1300 are continuous patterns, the protruding patterns 1300 may be ring protruding patterns, as shown in FIGS. 4A and 4B. If the protruding patterns 1300 are discontinuous patterns, each of the protruding patterns 1300 includes a plurality of protuberances 1310 separated from each other, as shown in FIGS. 4C, 4D, and 4E.

Referring to FIG. 3 again, the passivation layer 1400 covers on the circuit units 1110, the pads 1200, and the protruding patterns 1300. Furthermore, the passivation layer 1400 has a plurality of openings 1410, each of which exposes a part of one of the pads 1200. It should be noted that, since a height difference exists between the surface of each of the pads 1200 and the surface of each of the circuit units 1110, and between the surface of each of the protruding patterns 1300 and the surface of each of the circuit units 1110, the passivation layer 1400 around each of the pads 1200 and the passivation layer 1400 on each of the protruding patterns 1300 respectively has a protrusion pattern Si and a protrusion pattern S2, wherein the shape of each of the protrusion patterns SI corresponds to the shape of the border of one of the pads 1200, and the shape of each of the protrusion patterns S2 corresponds to the shape of one of the protruding patterns 1300.

The material of the bumps 1500 is, for example, gold or other conductive materials. The bumps 1500 are formed on the passivation layer 1400 by means of electroplating, wherein each of the bumps 1500 is electrically connected to corresponding one of the pads 1200 and overlaps corresponding one of the protruding patterns 1300 and corresponding one of the pads 1200. Since the passivation layer 1400 has the protrusion patterns S1 and the protrusion patterns S2, the top surface 1510 of each of the bumps 1500 has a protrusion pattern T1 and a protrusion pattern T2 corresponding to one of the protrusion patterns S1 and one of the protrusion patterns S2, respectively. In addition, in order to enhance the bond strength between each of the bumps 1500 and the corresponding one of the pads 1200, in this embodiment, a UBM layer 1600 is disposed between one of the bumps 1500 and one of the pads 1200, wherein each of the UBM layers 1600 is electrically connected to one of the bumps 1500 and electrically connected to one of the pads 1200 through one of the openings 1410.

Based on the wafer structure 1000, in this embodiment, a sawing process is further performed on the wafer structure 1000 to form a plurality of chip structures. Referring to FIG. 5, a schematic view showing a chip structure sawed from the wafer structure in FIG. 3, the chip structure 2000 includes a substrate 1100, at least one pad 1200, at least one protruding pattern 1300, a passivation layer 1400, and at least one bump 1500. The connection relations and relative positions of each of the components in the chip structure 2000 are similar to those in the wafer structure 1000 and will not be described herein.

In view of the above, under the circumstance that the size of the bumps in the present invention is the same as that of the bumps in the conventional drive chip, since each of the bumps in the present invention overlaps the corresponding one of the pads and the corresponding one of the protruding patterns, compared with the conventional art, a suitable distance is easily retained between each of the openings and the wall of corresponding one of the bumps, so as to protect the aluminum pads from being contaminated during the process of forming the bumps. In addition, when the chip structure in the present invention is electrically connected to a circuit device through an ACF, since the ratio of the area of the protrusion portion on the surface of each of the bumps to the area of the top surface of the bump is reduced due to the design provided by the present invention, the pressing force applied from the bumps to the conductive particles may be increased to enhance the reliability of the electrical connection between the chip structure and the circuit device when the chip structure is pressed onto the circuit device.

Additionally, compared with the conventional art, in the present invention, the protrusions patterns corresponding to the protruding patterns are further formed on the top surfaces of the bumps; therefore, during the pressing process, it is easier to trap the conductive particles on the surfaces of the bumps, thereby enhancing the yield of the pressing process.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A chip structure, comprising:
a substrate, having a circuit unit;
at least one pad, disposed on the circuit unit;
at least one protruding pattern, disposed on the circuit unit and surrounding the pad;
a passivation layer, covering the circuit unit, the pad, and the protruding pattern, wherein the passivation layer has at least one opening exposing a portion of the pad; and
at least one bump, disposed on the passivation layer and electrically connected to the pad, wherein the bump overlaps the protruding pattern and the pad, and a top surface of the bump has a protrusion pattern corresponding to the protruding pattern.

2. The chip structure as claimed in claim 1, further comprising an under ball metallurgy (UBM) layer disposed on the passivation layer and between the bump and the pad.

3. The chip structure as claimed in claim 1, wherein the protruding pattern is not connected to the pad.

4. The chip structure as claimed in claim 1, wherein a material of the protruding pattern is metal.

5. The chip structure as claimed in claim 4, wherein a material of the protruding pattern is the same as that of the pad.

6. The chip structure as claimed in claim 1, wherein the protruding pattern is a continuous pattern.

7. The chip structure as claimed in claim 6, wherein the protruding pattern is a ring protruding pattern.

8. The chip structure as claimed in claim 1, wherein the protruding pattern is a discontinuous pattern.

9. The chip structure as claimed in claim 8, wherein the protruding pattern comprises a plurality of protuberances separated from each other.

10. The chip structure as claimed in claim 1, wherein a material of the bump is gold.

11. A wafer structure, comprising:
a substrate, having a plurality of circuit units;
a plurality of pads, disposed on the circuit units;
a plurality of protruding patterns, disposed on the circuit units, wherein each of the protruding patterns surrounds the corresponding one of the pads;
a passivation layer, covering the circuit units, the pads, and the protruding patterns, wherein the passivation layer has a plurality of openings each of which exposes a part of one of the pads; and
a plurality of bumps, disposed on the passivation layer and electrically connected to the pads, wherein each of the bumps overlaps the corresponding one of the protruding patterns and the corresponding one of the pads, and top surfaces of the bumps have protrusion patterns corresponding to the protruding patterns.

12. The wafer structure as claimed in claim 11, further comprising a plurality of UBM layers disposed on the passivation layer and between the bumps and the pads.

13. The wafer structure as claimed in claim 11, wherein the protruding patterns are not connected to the pads.

14. The wafer structure as claimed in claim 11, wherein a material of the protruding patterns is metal.

15. The wafer structure as claimed in claim 14, wherein a material of the protruding patterns is the same as that of the pads.

16. The wafer structure as claimed in claim 11, wherein each of the protruding patterns is a continuous pattern.

17. The wafer structure as claimed in claim 16, wherein each of the protruding patterns comprises a ring protruding pattern.

18. The wafer structure as claimed in claim 11, wherein each of the protruding patterns is a discontinuous pattern.

19. The wafer structure as claimed in claim 18, wherein each of the protruding patterns comprises a plurality of protuberances separated from each other.
